(19) United States
(12) Patent Application Publication
(10) Pub. No.: US 2013/0008484 A1
(43) Pub. Date: Jan. 10, 2013

(54) INCREMENTALLY POSITIONED SOLAR ARRAY

(76) Inventor: Karl S. Weibezahn, Corvallis, OR (US)

(21) Appl. No.: 13/176,474

(22) Filed: Jul. 5, 2011

(51) Int. Cl. H01L 31/052; F24J 2/38; F24J 2/12; H01L 31/0232; F24J 2/04

(52) U.S. Cl. 136/246; 126/600; 136/259; 126/608; 126/634; 126/694; 126/581

(57) ABSTRACT

Apparatus and methods related to solar energy are provided. A system includes a solar array supported to be angularly repositionable. A shuttle and linkage arrangement is coupled to the solar array. Thermally activated actuators sequentially control the linear translation of the shuttle such that the solar array is incrementally angularly repositioned over the course of a daylight period. Concentrated solar energy is used to heat the actuators in their sequential order. Systems for generating electrical and/or thermal energy, embodied as panels or other form-factors, are contemplated.

### STATEMENT OF GOVERNMENT INTEREST

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Solar energy systems provide useful energy such as electricity or thermal heating by way of incident photonic energy, such as sunlight. Improvements to such solar systems are continuously sought after. The present teachings address the foregoing concerns.

### BRIEF DESCRIPTION OF THE DRAWINGS

The present embodiments will now be described, by way of example, with reference to the accompanying drawings, in which:

FIG. 1A depicts a schematic view of a device in a first operating state according to one example;

FIG. 1B depicts a schematic view of the device of FIG. 1A in a second operating state;

FIG. 2 depicts an isometric-like view of a solar energy system according to another example;

FIG. 3 depicts an isometric-like view of a solar energy system according to yet another example;

FIG. 4 depicts a schematic view of respective actuators according to an example;

FIG. 5 depicts a schematic view of a sub-system according to another example;

FIG. 6 depicts a block diagram of a solar energy system according to an example;

FIG. 7 depicts a flow diagram of a method according to another example.

### DETAILED DESCRIPTION

### Introduction

Methods and apparatus related to solar energy systems are provided. A system includes a solar array pivotally supported to be angularly repositionable. A shuttle and linkage arrangement is coupled to the solar array. Thermally activated actuators control the linear advancement of the shuttle in discrete steps such that the solar array is incrementally angularly repositioned over the course of a daylight period. Concentrated solar energy is used to heat the actuators in a sequential order. Systems for generating electrical and/or thermal energy, embodied as panels or other form-factors, are contemplated.

In one example, a device includes a photonic energy receiver supported to be angularly positioned. The device also includes a shuttle that is mechanically coupled to the photonic energy receiver such that linear positioning of the shuttle causes angular positioning of the photonic energy receiver. The device further includes a spring to bias the shuttle toward an end position. The device also includes an actuator configured to hold fast the shuttle against the spring biasing when in a first state. The actuator is also configured to be disengaged from the shuttle when in a second state. The device further includes an optical element to concentrate photonic energy so as to thermally activate the actuator from the first state to the second state.

In another example, a solar energy system including a solar array to convert incident photonic energy into electrical energy. The solar array is angularly positionable. The system also includes a shuttle coupled so as to angularly position the solar array by way of linear positioning of the shuttle. The system also includes a spring coupled to bias the shuttle in a first direction. The system further includes a plurality of bimetallic actuators. Each of the bimetallic actuators is configured to mechanically engage the shuttle in first state and to mechanically disengage the shuttle in a second state. Each bimetallic actuator is also configured to be changed from the first state to the second state by way of solar energy heating. The system also includes an optical element to concentrate solar energy onto the bimetallic actuators in a sequential order in accordance with the apparent motion of the sun. The system further includes a handle coupled to position the shuttle in a second direction opposite the first direction in response to a user input.

In yet another example, a system including a solar array and a plurality of bimetallic actuators. The bimetallic actuators are mechanically coupled so as to incrementally angularly position the solar array in accordance with the apparent motion of the sun.

### First Illustrative Device

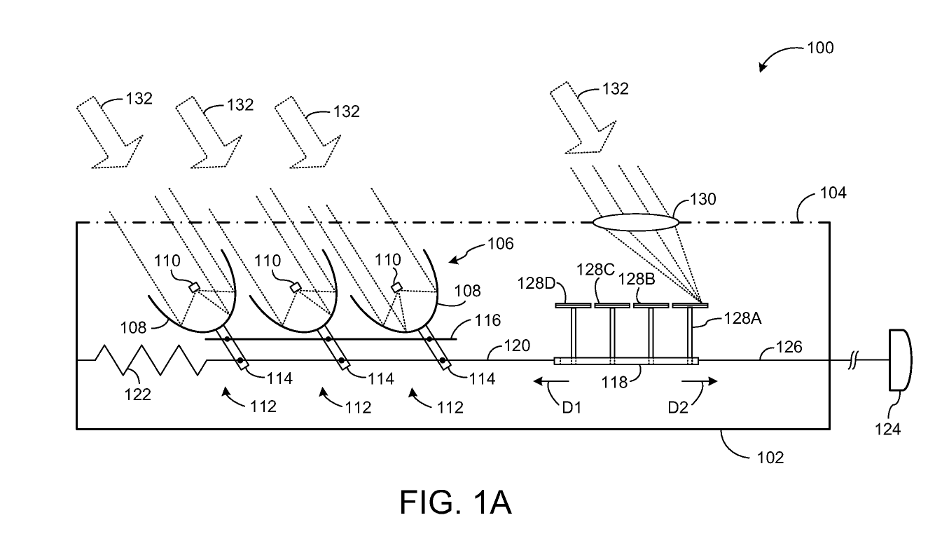

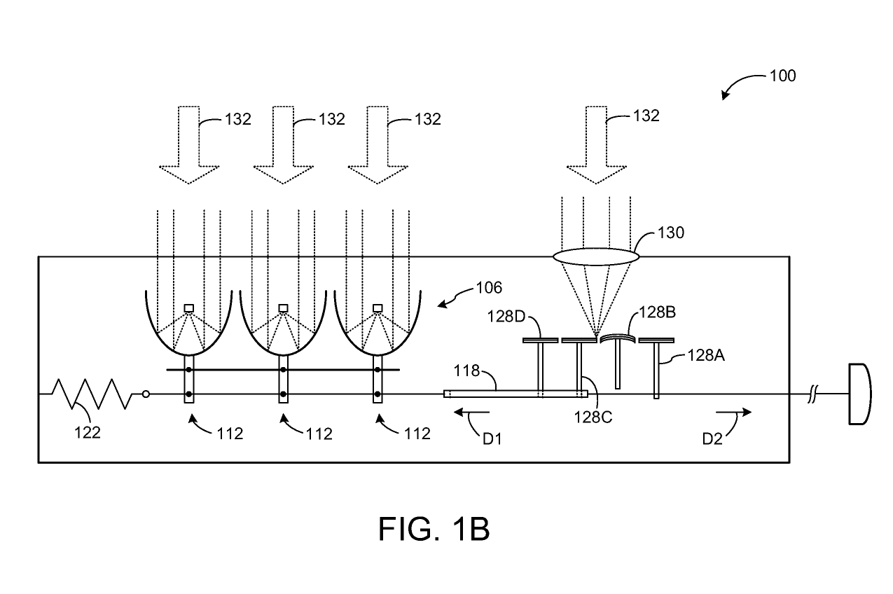

Reference is now directed to FIG. 1A, which depicts a schematic view of a device 100. The device 100 is illustrative and non-limiting in nature. Thus, other devices, apparatus and systems are contemplated by the present teachings. The device 100 is also referred to as a photonic energy device or solar energy device (or system) 100 for purposes herein. The device 100 of FIG. 1A is depicted in a starting or “sunrise” operating state.

The device (or system) 100 includes a housing 102, which includes a transparent cover or window 104. The housing 102 can be formed from any suitable material such as, for non-limiting example, metal, wood, plastic, synthetic laminates, carbon fiber, fiberglass, and so on. Other suitable materials can also be used. In turn, the transparent cover 104 can be formed from glass, plastic, and so on. Other suitable transparent materials can also be used.

The device 100 also includes a solar array 106. It is noted that the solar array 106 is disposed or support within (or substantially so) the housing 102 and underlying the transparent cover 104. The solar array 106 includes three photonic (solar) energy concentrators 108 each in the form of a reflective parabolic trough. Each photonic energy concentrator 108 is configured to concentrate incident photonic energy, such as sunlight, onto a target region or entity 110. In one example, each of the target entities 110 includes one or more photovoltaic cells. In another example, each target entity 110 includes or is defined by a fluid-filled thermal energy transfer conduit. Other suitable targets 110 can also be used. Each of the target entities 110 is supported at an energy concentration region (i.e., focal point or strip) defined by the corresponding photonic energy concentrator 108. Each photonic energy concentrator 108 and its respective target entities 110 are collectively referred to as a photonic energy receiver 112.

Each photonic energy receiver 112 is supported by a pivot arm 114 so as to be pivoted or rotated about a respective axis. These axes are distributed along a line 116 in the interest of clarity. Thus, each photonic energy receiver 112 is angularly positionable about its respective support axis by way of a linear input coupled to its respective pivot arm 114.

The device 100 includes a shuttle 118. In example, the shuttle 118 is defined by a slotted collar. Other suitable shuttle 118 form-factors can also be used. The shuttle 118 is formed from solid material such as metal, plastic, and so on and is mechanically coupled to the respective pivot arms 114 by way of a linkage 120. The shuttle 118 is support or guided to be bidirectionally linearly positioned. Linear positioning of the shuttle 118 results in angular positioning of the photonic energy receivers 112 (i.e., the solar array 106) by way of the pivot arms 114 and the linkage 120.

The device 100 also includes a spring 122. The spring 122 is anchored directly or indirectly to the housing 102 and is also coupled to the linkage 120. The spring 122 operates to bias the shuttle 118 in a first direction “D1”. Positioning of the shuttle 118 in the direction D1 results in a corresponding angular positioning of the photonic energy receivers 112. The spring 122 can be defined by a metallic helical spring, a coiled torsion spring, a plastic spring, an elastic band or bundling of elastic elements, and so on. Other suitable types of spring 122 can also be used.

The device 100 also includes a handle 124 coupled to the shuttle 118 by way of a linkage 126. The handle 124 functions to position the shuttle 118 in a direction “D2” against the biasing of the spring 122 by way of a user manipulation or manual input force. Positioning of the shuttle 118 in the direction D2 results in a corresponding angular positioning of the photonic energy receivers 112 to theft respective positions as depicted in FIG. 1. The handle 124 is also referred to as a reset or pull handle 124 for purposes herein.

The device 100 further includes a plurality of bimetallic actuators (actuators) 128A, 128B, 128C and 128D. The actuators 128A-128D are each defined by a first state when relatively cool (i.e., about ambient temperature), and a second state when heated sufficiently above ambient temperature. Additionally, each actuator 128A-128D is disposed to mechanically engage the shuttle 118 and to hold it fast against the biasing force of the spring 122 when in the first state. Each actuator 128A-128D is also disposed to mechanically disengage from the shuttle 118 so as to not impede its motion when in the second state.

The actuators 128A-128D are arranged such that the shuttle 118 is held fast by each in a sequential order. That is, the shuttle 118 is engaged by the actuators 128A-128D one at a time, in turn order, as the shuttle 118 is incrementally drawn in the direction D1 by way of the spring 122. Thus, as depicted in FIG. 1A; the actuator 128A is engaged so as to hold the shuttle 118 fast against the force of the spring 122. As a result, the shuttle 118 and the solar array 106 are stationary in their respective positions. The device 100 is in a starting or “sunrise” state as depicted by FIG. 1A.

The device 100 further includes an optical element 130. The optical element 130 can include or be defined by one or more lenses, a Fresnel lens, an array of light pipes, and so on. Other optical elements 130 can also be used. The optical element 130 is disposed to concentrate incident photonic energy (sunlight) onto the bimetallic actuators 128A-128D in a sequential order, beginning with actuator 128A. In one non-limiting example, the optical element 130 receives incident sunlight 132 and concentrates it upon the actuators 128A-128D, in order, in accordance with the apparent motion of the sun across the sky. Other operating examples can also be used.

The solar energy device 100 is configured so that incident photonic energy 132, such as sunlight, is received through the transparent cover 104 and is concentrated onto the target entities 110. For non-limiting example, it is assumed that the target entities 110 are defined by respective photovoltaic (PI) cells configured to generate electrical energy by direct conversion.

The angular position of the solar array 106 is determined by the linear positioning of the shuttle 118. In turn, the shuttle 118 is drawn or biased in the direction D1 under the influence of the spring 122. The bimetallic actuators 128A-128D regulate the incremental advancement of the shuttle 118 in the direction D1 by individual engagement therewith. As each actuator 128A-128D is sequentially triggered (i.e., activated or changed) from a first state to a second state, the shuttle 118 is allowed to advance to its next incremental position in the direction D1. The solar array 106 is incrementally angularly repositioned by these discrete advancements of the shuttle 118.

The optical element 130 operates to concentrate sunlight 132 onto the bimetallic actuators 128A-128D in sequential order, progressing in accordance with the apparent motion of the sun. The particular bimetallic actuator 128A-128D being heated by way of the optical element 130 eventually reaches a threshold temperature and moves from the first state to the second state. The shuttle 118 then advances in the direction D1 and into “hold fast” engagement with the next bimetallic actuator 128A-128D in the sequence, repositioning the solar array 106 accordingly.

The incremental positioning of the shuttle 118 and the solar array 106 continues in the manner described above until an end or “sunset” state is reached. Cooling of the respective actuators 128A-128D returns them to their first state. A user repositions the shuttle 118 back in the direction D2 by way of the handle 124 and the solar energy device 100 is now “reset” for another normal operation. The movement or change from the first state to the second state (or vice-versa) of the respective actuators 128A-128D can be relatively rapid or “snap acting” (about instantaneous), or it can be relatively slower or gradual requiring several seconds or more. Other suitable rates-of-change between states can also be used.

Attention is now turned to FIG. 1B, which depicts the solar energy device 100 in an intermediate or “mid-day” (i.e., noon) operating state. The actuator 128A has been previously heated and changed to the second state, and has returned to the first state as a result of cooling. The actuator 128B has just been thermally changed and is still in the second state. The shuttle 118 has advanced in the direction D1 and is being held fast by the bimetallic actuator 1280, which is in the first state. In turn, the solar array 106 is angularly positioned so as to receive the noon-day sunlight 132.

The optical element 130 is now beginning to concentrate sunlight 132 onto the bimetallic actuator 128C such that heating thereof is underway. The actuator 128C will change from the first state to the second state once it has been sufficiently heated, disengaging the shuttle 118. The shuttle 118 will then linearly translate, under the influence of the spring 122, into engagement with the actuator 1280, which is in the first state. The solar array 106 will be angularly repositioned accordingly at that time.

The solar energy device (or system) 100 is illustrative of just one example contemplated by the present teachings. It is noted that that the device 100 includes just four actuators 128A-1280 in the interest of clarity. However, it is to be understood that the present teachings contemplate other embodiments having any suitable number of bimetallic actuators (e.g., ten, twenty, and so on). Increasing the number of actuators increases the incremental resolution during operation. That is, the angular orientation of the solar array 106 can be controlled with increased resolution and lesser angular error by increasing the number actuators used.

### Illustrative System

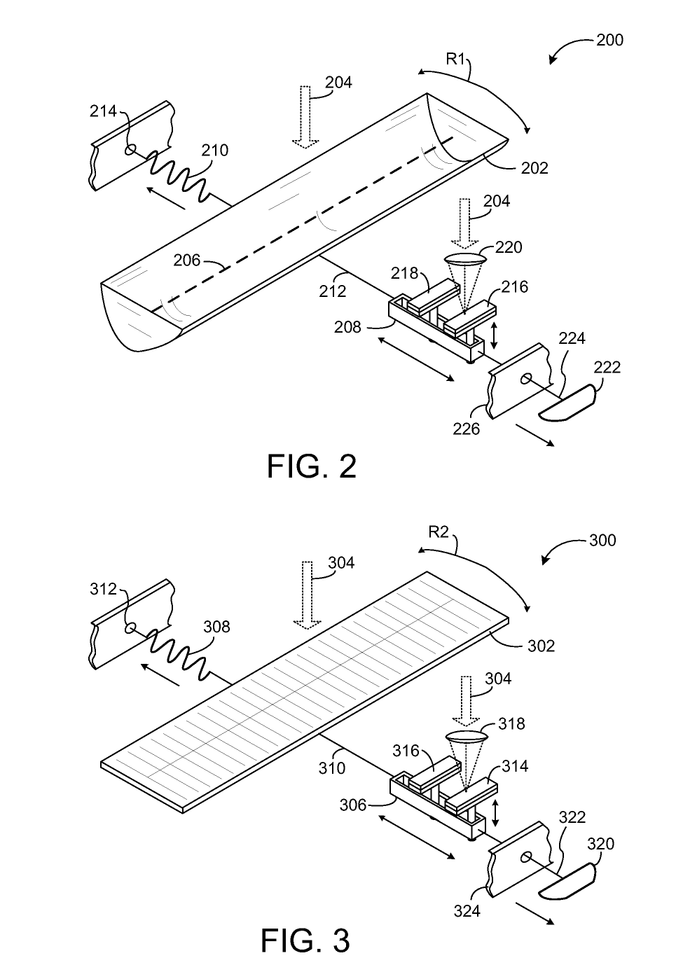

Reference is now made to FIG. 2, which depicts an isometric-like view of a solar energy system 200 in accordance with another example. The system 200 is illustrative and non-limiting with respect to the present teachings. Other systems, devices, and apparatus can also be used.

The system 200 includes a parabolic reflector or concentrator 202. The concentrator 202 functions to concentrate incident photonic energy 204, such as sunlight, onto a strip- or bar-like target region 206. The target region 206 can be occupied, for non-limiting example, by a photovoltaic cell or linear array thereof, by a fluid-filled thermal energy transfer conduit, and so on. Other entities and devices can also be used. The concentrator 202 is pivotally supported to be angularly positioned within a range of arc “R1”.

The system 200 also includes a shuttle 208. The shuttle 208 is in the form of a slotted collar or box and is linearly positionable or translatable in two opposite directions as depicted. The shuttle 208 can be formed from plastic, metal, or another suitable material. The system 200 also includes a spring 210. The spring 210 can be formed from metal, plastic, elastic material or another suitable material and can be of any suitable form-factor. The spring 210 is coupled to the shuttle 208 by a linkage 212. The spring 210 functions to urge or bias the shuttle 208 toward an end location 214. The concentrator 202 is coupled to the linkage 212 so as to be angularly positioned in accordance with linear positioning of the shuttle 208.

The system 200 also includes respective actuators 216 and 218. Two actuators 216 and 218 are shown in the interest of clarity. Any suitable number of actuators can be used in other examples. Each of the actuators 216 and 218 is also referred to as a bimetallic actuator for purposes herein and is defined by a first operating state and a second operating state, respectively.

Each actuator 216-218 is configured to mechanically engage the shuttle 208 and to hold it fast against the biasing force of the spring 210. As depicted, the actuator 216 is engaged to the shuttle 208, while the actuator 218 is next in the sequence to do so. The actuators 216-218 are thermally activated to move or change from the first state to the second state in response to heating, and from the second state back to the first state in response to cooling. The actuators 216-218 are both depicted in the first or “engagement” state. Conversely, each actuator 216-218 would be drawn away from the shuttle 208 when in the second or “disengagement” state.

The system 200 also includes an optical element 220 to concentrate photonic energy 204 onto a corresponding one of the actuators 216-218 in accordance with the position of the sun relative to the system 200. In particular, the optical element 220 sweeps a concentrated beam of sunlight 204 across the bimetallic aspects of the actuators 216-218, smoothly progressing from one to the next, as the sun moves relative to the system 200. The actuators 216-218 are thus thermally triggered in sequential order, allowing the shuttle 208 to incrementally advance toward the end location 214. The concentrator 202 is angularly repositioned in corresponding increments, accordingly.

The system 200 also includes a pull handle 222 coupled to the shuttle 208 by a linkage 224. The linkage 224 is shown to pass through a penetration in a wall portion 226 that is part of a housing about at least a majority of the system 200. The pull handle 222 operates to reposition the shuttle 208 away from the end location 214 by way of user input. Such repositioning is normally performed at the end of a day's operation to prepare the system 200 for another operation beginning at or near sunrise on the next day.

### Another Illustrative System

Attention is directed now to FIG. 3, which depicts an isometric-like view of a solar energy system 300 in accordance with another example. The system 300 is illustrative and non-limiting with respect to the present teachings. Other systems, devices, and apparatus can also be used.

The system 300 includes a photovoltaic (PV) cell 302. The PV cell 302 functions to generate electrical energy by direct conversion of incident photonic energy 304, such as sunlight. Other entities and devices can also be used in place of the PV cell 302. The PV cell 302 is pivotally supported to be angularly positioned within a range of arc “R2”.

The system 300 also includes a shuttle 306 that is analogous to the shuttle 208 as described above. Thus, the shuttle 306 is in the form of a slotted collar or box and is linearly positionable in two opposite directions as depicted. The shuttle can be formed from plastic, metal, or another suitable material. The system 300 also includes a spring 308 that is analogous to the spring 210 described above and can be similarly defined.

The spring 308 is coupled to the shuttle 306 by a linkage 310. The spring 308 urges or biases the shuttle 306 toward an end location 312. The PV cell 302 is coupled to the linkage 310 so as to be angularly positioned in accordance with linear positioning of the shuttle 306.

The system 300 also includes respective actuators 314 and 316, which are analogous to the actuators 216 and 218, respectively. While two actuators 314-316 are depicted, any suitable number of actuators can be used in other examples. Each of the actuators 314 and 316 is also referred to as bimetallic actuator and is defined by first and second operating states as described above.

Each actuator 314-316 is configured to mechanically engage the shuttle 306 and to hold it fast against the force of the spring 308. The actuators 314-316 are both depicted in the first or “engagement” state. Conversely, each actuator 314-316 would be drawn away from the shuttle 306 when in the second or “disengagement” state.

The system 300 also includes an optical element 318 to concentrate photonic energy 304 onto a corresponding one of the actuators 314-316 in accordance with the relative position of the sun. A concentrated beam of sunlight 304 is swept across each of the actuators 314-316, smoothly progressing from one to the next, as the sun moves relative to the system 300. The actuators 314-316 are thermally triggered in sequential order and the shuttle 306 advances incrementally toward the end location 312 accordingly. The PV cell 302 is incrementally angularly repositioned, accordingly.

The system 300 also includes a pull handle 320 coupled to the shuttle 306 by a linkage 322. The linkage 322 is shown to pass through a wall portion 324 that is understood to be a part of a housing. The pull handle 322 is used to reposition the shuttle 306 away from the end location 312 by way of user input. Such repositioning is normally performed to prepare the system 300 for another operation beginning at or near sunrise on the next day.

### Illustrative Actuators

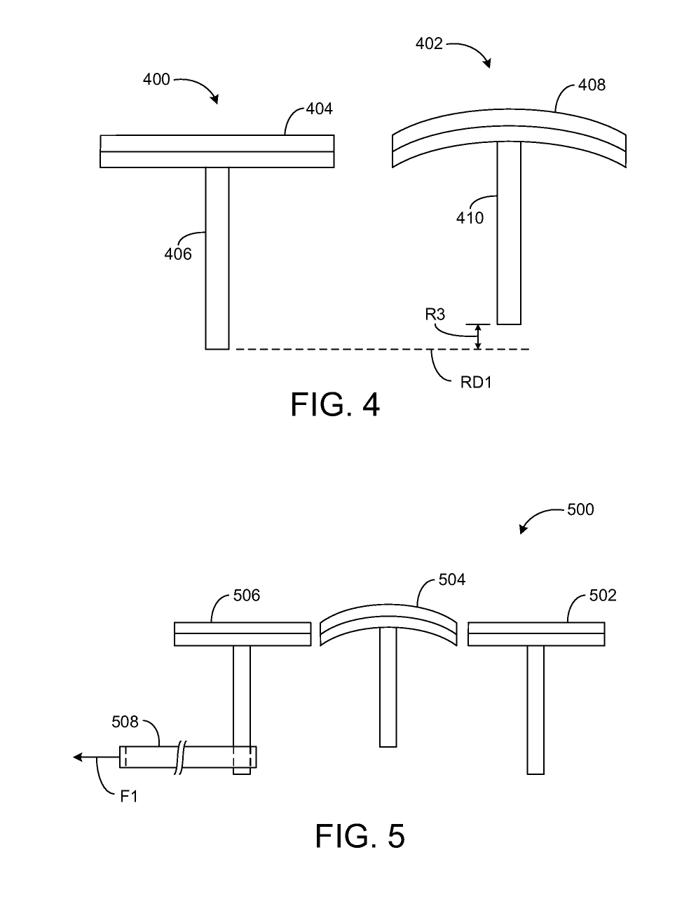

Reference is now made to FIG. 4, which depicts a schematic view of respective actuators 400 and 402, according to another example. The actuators 400 and 402 are illustrative and non-limiting with respect to the present teachings. Other actuators having other constituencies, form-factors or other characteristics can also be used. The actuators 400 and 402 are equivalent to one another in constituency, dimensions and operating characteristics, and are also referred to as bimetallic actuators for purposes herein.

The actuator 400 includes a bimetallic element 404 and a linear rod 406. The actuator 400 is depicted in a first state corresponding to a cooled or ambient temperature condition. As such, the bimetallic element 404 is characterized by substantially planar condition such that the linear rod 406 is in an extended state. Thus, the first state of the actuator 400 is also characterized by an extension or base state of the linear rod 406. The bimetallic element 404 can be defined by a layer of brass metal joined to a layer of steel metal. Other materials can also be used.

The actuator 402 includes a bimetallic element 408 and a linear rod 410. The actuator 402 is depicted in a second state corresponding to a heated temperature condition. The bimetallic element 408 is characterized by a convex or upwardly arced condition such that the linear rod 410 is in a retracted or withdrawn state. It is noted that a range of motion “R3” is defined between the first state and second state with respect to a reference datum “RD1”. Thus, the respective linear rods 406 and 410 are offset or elevationally displaced by the distance R3. In one example, the distance R3 is about three millimeters. Other ranges of motion R3 can also be defined and used.

In one example, the actuators 400 and 402 change or move from the first state (e.g., actuator 400) to the second state (e.g., actuator 402) when their respective bimetallic element 404 or 408 is heated to greater than one-hundred degrees Fahrenheit above ambient temperature. In turn, the actuators 400 and 402 change from the second state back to the first state when cooled back to or about ambient temperature. Thus, the actuators 400 and 402 are characterized by a maximum operating temperature of about three-hundred degrees Fahrenheit. Other examples corresponding to other temperature values can also be used.

### Illustrative Sub-System

Reference is now made to FIG. 5, which depicts a schematic view of a sub-system 500 according to another example. The sub-system 500 is illustrative and non-limiting in nature, and other sub-systems, systems, and devices and apparatus can also be used. The sub-system 500 is depicted in the interest of clarity, and represents aspects that can be used in one or more systems according to the present teachings.

The sub-system 500 includes respective bimetallic actuators (actuators) 502, 504 and 506. The actuators 502 and 504 and 506 are arranged in a linear row or sequence and are thermally activated in order during normal operations. The actuators 502-506 can be supported such that each is capable of normal, independent operation.

Each of the actuators 502-506 is configured to be activated or changed from a first state to a second state by photonic energy (sunlight) heating. The actuator 504 is in a second state corresponding to a heated or recently heated condition. The actuators 502 and 506 are each in a first state corresponding to a cooled or ambient temperature condition.

The sub-system 500 also includes a shuttle 508 configured to be mechanically engaged by the respective actuators 502-506 in sequential order. The shuttle 508 is biased to be linearly displaced by a force “F1”. Such a force F1 can be provided by way of loaded spring or similar entity (e.g., spring 122). The shuttle 508 is configured to move in the direction of the force F1, advancing incrementally from the actuator 502 to the actuator 504, and then to the actuator 506. As depicted, the shuttle 508 is mechanically engaged by the actuator 506 and is held fast against the displacement force F1 accordingly.

A solar array (e.g., solar array 106) or other entity can be angularly positioned in accordance with the incremental advancement of the shuttle 508 by way of suitable mechanical coupling there between. The sub-system 500 can be used according to the present teachings such that respective, whole solar energy systems can be defined.

### Illustrative Block Diagram of a System

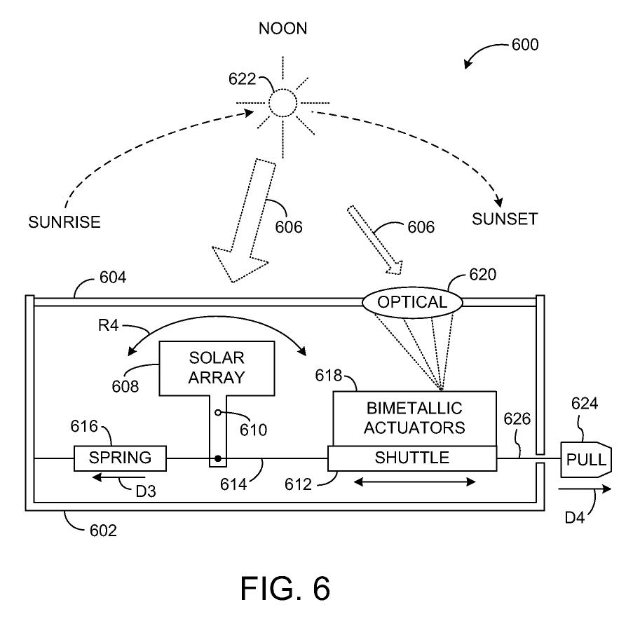

Attention is now directed to FIG. 6, which depicts a block diagram of a solar energy system (system) 600. The system 600 is illustrative and non-limiting in nature, and is directed to clarity of the present teachings. Other systems, devices and apparatus, and their respective operating characteristics, are also contemplated.

The system 600 includes a housing 602 having a transparent cover or window 604. The housing 602 can be made from any suitable material such as plastic, metal, fiberglass and so on, while the transparent cover 604 can be made from glass, acrylic, plastic and so on. The transparent cover 604 is such that at least some spectral content of incident photonic energy 606, such as sunlight, can propagate there through.

The system 600 also includes a solar array 608. The solar array 608 can include any suitable constituency such as photovoltaic cells, photonic energy concentrators, fluid-filled thermal energy transfer conduits, and so on. Other elements and devices can also be used. Energy derived by the solar array 608—electrical, thermal or both—can be communicated to various loads or entities external to the system 600. The solar array 608 is configured to be angularly positioned within a range “R4” by way of rotation about an axis 610.

The system 600 also includes a shuttle 612. The shuttle 612 can be bidirectionally translated as depicted and is coupled to the solar array 608 by way of a linkage 614. The system also includes a spring 616 coupled to the shuttle 612 by way of the linkage 614. The spring 616 is also anchored to the housing 602 by way of direct or indirect coupling. The spring 616 functions to bias or urge the shuttle in a direction “D3”.

The system 600 includes a plurality of bimetallic actuators (or actuators) 618. The plurality of actuators 618 is arranged to mechanically engage the shuttle 612, one at a time in a sequential order, so as to control the incremental advancement of the shuttle 612 in the direction D3. The plurality of bimetallic actuators 618 can include any suitable number of individual actuators. In one example, each actuator of the plurality 618 is equivalent to the bimetallic actuator 400 described above. Other actuators having other constituencies, characteristics or form-factors can also be used.

The system 600 also includes an optical element or device 620. The optical element 620 can be defined by any lens, Fresnel lens, configuration of lenses or light pipes, or other optical entities. The optical element 620 concentrates incident photonic energy (sunlight) 606 so as to heat the bimetallic actuators 618 in sequential order according to the apparent motion of the sun 622 across the sky. Heating of the bimetallic actuators 618 causes the shuttle 612 to progress incrementally in the direction D3, while the linkage 614 causes the solar array 608 to be angularly repositioned accordingly.

The system 600 also includes a pull handle (handle) 624 disposed outside of the housing 602 and coupled to the shuttle 612 by way of a linkage 626. The handle 624 functions to reposition the shuttle 612 in a direction “D4” opposite to the direction D3 in response to a user force input. The handle 624 therefore operates to reset the shuttle 612 back to a beginning or “sunrise” orientation with respect to the plurality of bimetallic actuators 618. In turn, the solar array 608 is angularly repositioned back to a corresponding sunrise orientation.

It is noted that a majority portion of the system 600 is disposed within the housing 602 and beneath the transparent cover 604. Examples of the system 600 can be constructed having a panel- or box-like form-factor, being essentially self contained and readily transportable. Such a form-factor also speeds the setup and operation of the system 600. The housing 602 protects internal elements such as the solar array 608, the bimetallic actuators 618, and so on, against rain and wind-blown debris and other environmental conditions during typical normal use.

### Illustrative Method

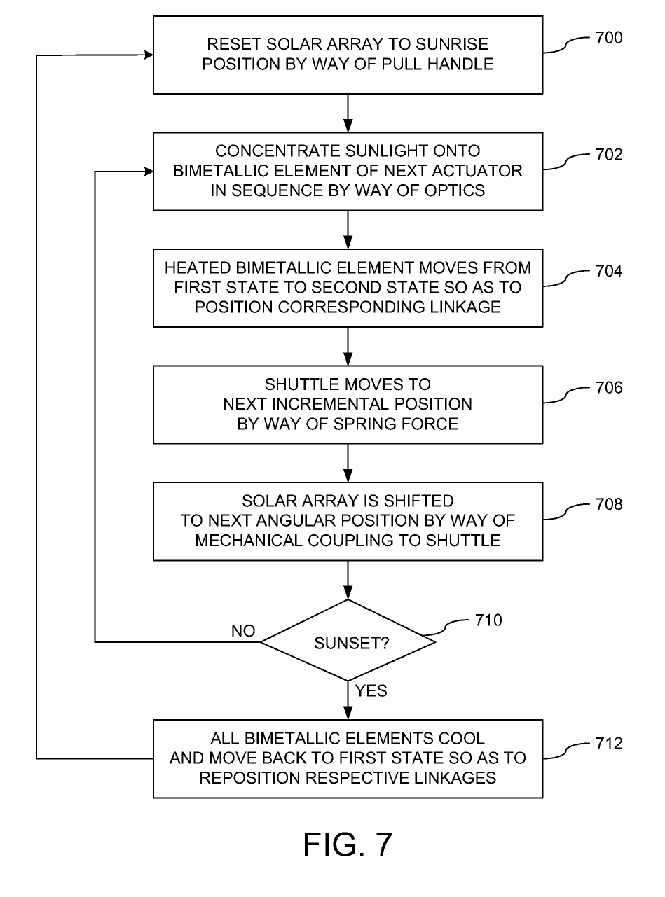

Reference is now made to FIG. 7, which depicts a flow diagram of a method according to another example of the present teachings. The method of FIG. 7 includes particular steps and proceeds in a particular order of execution. However, it is to be understood that other respective methods including other steps, omitting one or more of the depicted steps, or proceeding in other orders of execution can also be used. Thus, the method of FIG. 7 is illustrative and non-limiting with respect to the present teachings. Reference is also made to FIGS. 4 and 6 in the interest of understanding the method of FIG. 7.

At 700, a solar array is reset to a sunrise position by way of a pull handle. For purposes of a present example, a user applies a force to a pull handle 624 so as to draw a shuttle 612 in a direction D4, thus resetting the shuttle 612 to a sunrise or start position. The shuttle 612 is now engaged with the first in a sequence of plural bimetallic actuators (i.e., actuators) 618. A spring 616 is now loaded as a result of the positioning of the shuttle 612. A solar array 608 is angularly positioned by way of the shuttle 612 positioning to a corresponding sunrise orientation.

At 702, sunlight is concentrated onto a bimetallic element of a next actuator in the sequence by way of optics. For purposes of the present example, an optical element 620 is used to concentrate sunlight 606 onto the bimetallic element (e.g., 404) of the first bimetallic actuator 618 of the plurality. This first of the bimetallic actuators 618 begins to heat above ambient temperature, accordingly.

At 704, the heated bimetallic element moves from a first state to a second state so as to position a corresponding linkage. In the present example, the first of the bimetallic actuators 618 has been heated above a threshold temperature value and changes from a first state (e.g., see 400) to a second state (e.g., see 402). A corresponding linear rod (e.g., 406) is withdrawn out of engagement with the shuttle 612 as a result of the second state of the first of the bimetallic actuators 618.

At 706, the shuttle moves to the next incremental position by way of spring force. Under the present example, the shuttle 612 is drawn or translated in the direction D3 under the influence of the spring 616. The shuttle 612 moves into mechanical engagement with the next bimetallic actuator 618 in the sequence and is held fast against the spring 616 force. Thus, the shuttle 612 has advanced incrementally in the direction D3.

At 708, the solar array is shifted to a next angular position by way of mechanical coupling to the shuttle. In the present example, the solar array 608 is angularly shifted to a next position in the range R4 by way of the linkage 614 to the shuttle 612. The solar array 608 is now incrementally reoriented with respect to the sun 622.

At 710, it is determined if it is sunset. If it is sunset, then the method proceeds to step 712 below. If it is not yet sunset, then the method returns to step 702 above.

At 712, the bimetallic linkages cool and return from their first states so as to reposition the respective linkages. In the present example, all of the bimetallic actuators 618 cool back toward ambient temperature and move (or change) back to their first state (e.g., 400). All respective linear rods (e.g., 406) are extended into position for sequential engagement with the shuttle 612 during the next daily operation. The method then returns to step 700 above. One operation of the method of FIG. 7, spanning one day, is now complete.

In the method described above, the bimetallic actuators 618 were described as changing from the second (heated) state back to the first (ambient) state within a single step 712 in the interest of clarity. However, it is to be understood that actuators as contemplated by the present teachings can cool and move (or change) from the second state to the first state in any suitable time frame (i.e., minutes, seconds, a fraction of a second, and so on). Thus, a particular actuator can cool and change from a second state back to a first state within, say, a few seconds. Such a relatively short time frame is acceptable, provided that sufficient dwell time is spent in the second state for the corresponding shuttle (e.g., 118) to translate into engagement with the next actuator in the sequence.

In general and without limitation, the present teachings contemplate various device and systems and methods of their use. A system includes a solar array to generate electrical or thermal energy (or both) by way of incident photonic energy, such as sunlight. The solar array is typically—but not necessarily—supported within a housing having a transparent cover or window.

The solar array is mechanically coupled to a shuttle, which in turn is biased to translate in a first direction by way of a spring. Translation or repositioning of the shuttle results in angular repositioning of the solar array. Thermally activated actuators or bimetallic actuators are arranged to engage the shuttle, one at a time in a sequential order, and hold the shuttle fast against the spring biasing force.

An optical element or arrangement of such elements is used to concentrate photonic energy onto the actuators in their sequential order according to the apparent motion of the sun across the sky. The actuators are individually thermally activated from a first engagement state to a second disengagement state such that the shuttle incrementally progresses in the first direction over the course of one daylight period. The solar array is incrementally angularly repositioned during this daylight period by way of mechanical coupling to the advancing shuttle.

A pull handle and corresponding mechanical linkage enables a user to reposition the shuttle in a second direction opposite the first. Typically, such a manual operation is performed at the end of the daylight period so as to reset the system for the next operating cycle. The present teachings contemplate solar energy system having essentially self-contained, panel-like form-factors that can be readily transported, setup and operated under a variety of field conditions.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A device, comprising:
a photonic energy receiver supported to be angularly positioned;
a shuttle mechanically coupled to the photonic energy receiver such that linear positioning of the shuttle causes angular positioning of the photonic energy receiver;
a spring to bias the shuttle toward an end position;
an actuator to hold fast the shuttle against the spring biasing when in a first state, the actuator disengaged from the shuttle when in a second state; and
an optical element to concentrate photonic energy so as to thermally activate the actuator from the first state to the second state.

2. The device according to claim 1, the photonic energy receiver including a photonic energy concentrator.

3. The device according to claim 1, the photonic energy receiver including a photovoltaic cell to generate electrical energy by direct conversion of incident photonic energy.

4. The device according to claim 1, the actuator including a bimetallic actuator to assume the first state in response to cooling, the bimetallic actuator to assume the second state in response to heating.

5. The device according to claim 1 further comprising a housing including a transparent cover.

6. The device according to claim 1 further comprising a handle mechanically coupled to position the shuttle toward a start position by way of a user input force.

7. The device according to claim 1, the photonic energy receiver including a conduit to transfer thermal energy to a fluid flow therein.

8. A solar energy system, comprising:
a solar array to convert incident photonic energy into electrical energy, the solar array being angularly positionable;
a shuttle coupled to angularly position the solar array by way of linear positioning of the shuttle;
a spring coupled to bias the shuttle in a first direction;
a plurality of bimetallic actuators each to mechanically engage the shuttle in first state and to mechanically disengage the shuttle in a second state, each bimetallic actuator to be changed from the first state to the second state by way of solar energy heating;
an optical element to concentrate solar energy onto the bimetallic actuators in a sequential order in accordance with the apparent motion of the sun; and
a handle coupled to position the shuttle in a second direction opposite the first direction in response to a user input.

9. The solar energy system according to claim 8, the solar array including a solar energy concentrator.

10. The solar energy system according to claim 8 further comprising a housing including a transparent cover, at least the solar array being disposed within the housing such that the solar energy system is defined by a panel-like form-factor.

11. A system, comprising:
a solar array; and
a plurality of bimetallic actuators mechanically coupled to incrementally angularly position the solar array in accordance with the apparent motion of the sun.

12. The system according to claim 11, the solar energy array including a parabolic trough reflector to concentrate incident solar energy onto a target entity.

13. The system according to claim 11, the solar energy array including at least a photovoltaic cell, or a thermal energy transfer conduit.

14. The system according to claim 11 further comprising an optical element to concentrate solar energy onto the bimetallic actuators in a sequential order in accordance with the apparent motion of the sun.

15. The system according to claim 11 further comprising a housing disposed about the solar energy array, the housing including a transparent cover through which incident solar energy propagates prior to striking the solar energy array.
